(19) United States
(12) Patent Application Publication
(10) Pub. No.: US 2026/0196824 A1
(43) Pub. Date: Jul. 9, 2026

(54) SOFTWARE CONTROLLED SOLID-STATE SWITCH

(71) Applicant: VISTEON GLOBAL TECHNOLOGIES, INC., Van Buren Township, MI (US)

(72) Inventors: He Niu, South Lyon, MI (US); Luis Filipe Cabrito Reis, Barreiro (PT); Kiril S. Paunov, Plovdiv (BG); Zilai Zhao, Novi, MI (US)

(73) Assignee: VISTEON GLOBAL TECHNOLOGIES, INC., Van Buren Township, MI (US)

(21) Appl. No.: 19/435,995

(22) Filed: Dec. 30, 2025

Related U.S. Application Data
(60) Provisional application No. 63/741,520, filed on Jan. 3, 2025.

(51) Int. Cl. H02H 7/18; H02H 1/00; H03K 17/18; H03K 17/30

(52) U.S. Cl. CPC H02H 7/18; H02H 1/0007; H03K 17/18; H03K 17/302

(57) ABSTRACT

A solid-state switch includes a power board and a control board. The power board is operational to switch on/off a high-voltage current, measure the high-voltage current, and sense a high voltage. The control board includes a microcontroller unit and a bus interface circuit. The control board is operational to pass control signals from the microcontroller unit to the power board for switching of the high voltage current, and pass sensed data from the power board to the control board for the high voltage current and the high voltage. The microcontroller unit is operational to calculate a pre-charge detection, an ampere squared seconds detection, an over current detection, an over temperature detection, and a short circuit detection, and report the detections external to the control board via the bus interface circuit.

### CROSS-REFERENCE TO RELATED APPLICATIONS

This application claims the benefit of U.S. Provisional Application Number 63/741,520, filed January 3, 2025, which is hereby incorporated by reference in its entirety.

### TECHNICAL FIELD

The present disclosure generally relates to systems and methods for a software controlled solid-state switch.

### BACKGROUND

Existing solid-state switches are designed to switch on and switch off an electrical current. Unlike mechanical relays, the switching of a solid-state relay is bounce less. In some designs, the solid-state switches may also detect an overcurrent condition while in an on state and switch to an off state to stop the current flow. Such solid-state switches act as a solid-state circuit breaker with a performance defined in the hardware design.

Accordingly, those skilled in the art continue with research and development efforts in the field of software controlled solid-state switches.

### SUMMARY

A solid-state switch is provided herein. The solid-state switch includes a power board and a control board. The power board is operational to alternatively switch on and switch off a high-voltage current, measure the high-voltage current, and sense a high voltage of the high-voltage current. The control board operates from a low-voltage source and includes a microcontroller unit and a bus interface circuit. The control board is operational to pass a plurality of control signals from the microcontroller unit to the power board for switching of the high voltage current, and pass a plurality of sensed data from the power board to the microcontroller unit for the high voltage current and the high voltage. The microcontroller unit is operational to calculate a plurality of detections that include a pre-charge detection, an ampere squared seconds detection, an over current detection, an over temperature detection, and a short circuit detection, and report the plurality of detections external to the control board via the bus interface circuit.

The above features and advantages and other features and advantages of the present teachings are readily apparent from the following detailed description of the best modes for carrying out the teachings when taken in connection with the accompanying drawings.

### BRIEF DESCRIPTION OF THE DRAWINGS

FIG. 1 illustrates a schematic design of a software controlled solid-state switch in accordance with one or more exemplary embodiments.

FIG. 2 illustrates a flow diagram of a pre-charge detection and coordination method in accordance with one or more exemplary embodiments.

FIG. 3 illustrates a flow diagram of a It2 calculation method in accordance with one or more exemplary embodiments.

FIG. 4 illustrates a flow diagram of an over current detection method in accordance with one or more exemplary embodiments.

FIG. 5 illustrates a flow diagram of an over temperature detection method in accordance with one or more exemplary embodiments.

FIG. 6 illustrates a flow diagram of a short circuit detection method in accordance with one or more exemplary embodiments

FIG. 7 illustrates a flow diagram of a circuit breaker control method in accordance with one or more exemplary embodiments.

FIG. 8 illustrates a flow diagram of a battery management system interaction method in accordance with one or more exemplary embodiments.

FIG. 9 illustrates a flow diagram of a solid-state switch degradation and end of life method in accordance with one or more exemplary embodiments.

The present disclosure may have various modifications and alternative forms, and some representative embodiments are shown by way of example in the drawings and will be described in detail herein. Novel aspects of this disclosure are not limited to the particular forms illustrated in the above-enumerated drawings. Rather, the disclosure is to cover modifications, equivalents, and combinations falling within the scope of the disclosure as encompassed by the appended claims.

### DETAILED DESCRIPTION

Embodiments of the disclosure generally provide a solid-state switch, system and/or method that includes a microcontroller, current sensing, voltage sensing, and temperature sensing. By using software to regulate the sensing, the following functions may be achieved pre-charge detection, ampere squared seconds (I2t) calculations, over current detection, over temperature detection, and short circuit detection.

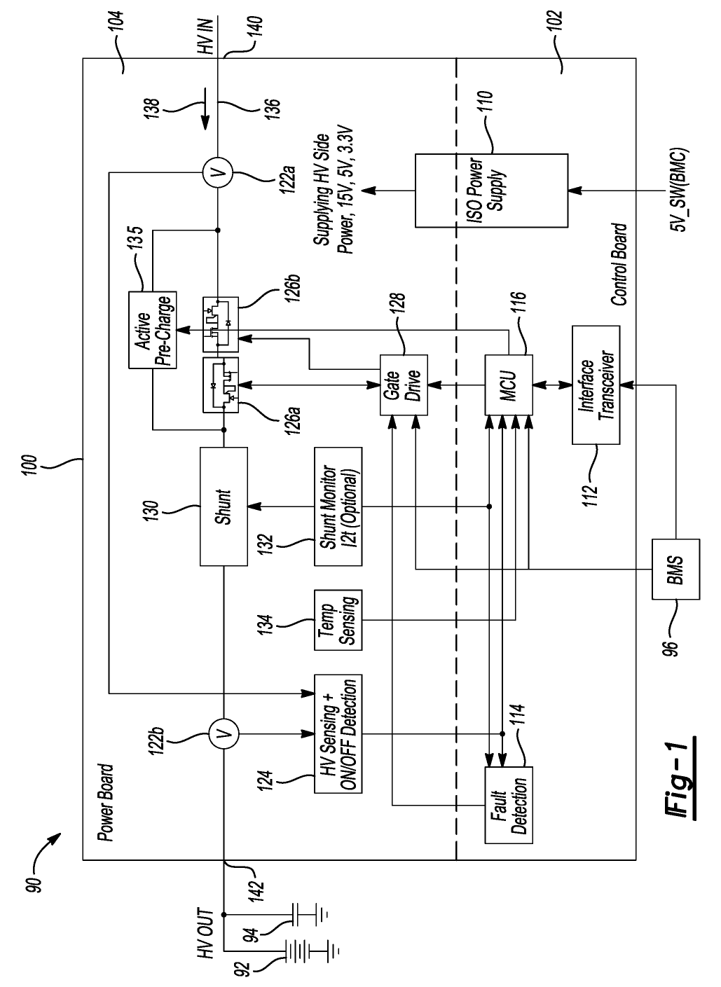

FIG. 1 illustrates a schematic design of an example implementation of a software-controlled system 90 in accordance with one or more exemplary embodiments. The system 90 generally includes a solid-state switch 100 coupled to a battery 92 with a capacitance 94, and a battery management system (BMS) 96. The solid-state switch 100 generally includes a control board 102 and a power board 104. The control board 102 may include a power supply circuit 110, a bus interface circuit 112, a fault detection circuit 114, and a microcontroller unit (MCU) 116. The power board 104 includes multiple high voltage measurement circuits 122a-122b, a high voltage sensing circuit 124, multiple power transistors 126a-126b, a gate driver circuit 128, a current sense circuit (or shunt) 130, a shunt monitor circuit 132, a temperature sensing circuit 134 and a pre-charge circuit 135.

In various embodiments, software executing on the microcontroller unit 116 provides current sensing, voltage sensing, and temperature sensing in the solid-state switch 100. Using the software, the following functions are achieved: pre-charge detection and coordination, I2t calculation, over current detection, over temperature detection, short circuit detection, controlled circuit breaking under a load, battery management system 96 interactions and local estimation on solid-state switch degradation and end of life. Results of the functions may be reported to other circuitry via the bus interface circuit 112. The solid-state switch and the other circuitry may reside within a vehicle.

The battery 92 implements a high-voltage battery. In various embodiments, the high voltage may range from approximately 48 volts DC to approximately 950 volts DC (e.g., 800 volts DC).

The capacitance 94 is a parasitic capacitance of the battery 92 and associated harnessing.

The battery management system 96 is operational to control a charging and discharging of the battery 92. The battery management system 96 may communicate with the solid-state switch 100 via the bus interface circuit 112 and discrete wire (e.g., an enable signal to the gate driver 128).

The control board 102 may operate from a low-voltage electrical power. In various embodiments, an input voltage may be approximately 12 volts DC.

The power board 104 may switch a high voltage current 138 at a high voltage 136 in response to control signals received from the microcontroller unit116.

The power supply circuit 110 may convert the 12 volts DC to approximately 5 volts DC, 15 volts DC and 3.3 volts DC. The 15 volt DC, the 5 volt DC and the 3.3 volt DC power may be presented to circuitry within the power board 104.

The bus interface circuit 112 implements a controller area network (CAN) vehicle bus interface circuit. The CAN bus was developed at Robert Bosch GmbH. In various embodiments, the bus interface circuit 112 may implement a controller area network flexible data-rate (CAN FD) bus. Other types of buses may be implemented to meet the design criteria of a particular application.

The fault detection circuit 114 is operational to detect faults involving the gate driver circuit 128. Detected faults may be reported to the microcontroller unit 116.

The microcontroller unit 116 is operational to calculate multiple detections that include, but are not limited to, a pre-charge detection, an ampere squared seconds detection, an over current detection, an over temperature detection, and a short circuit detection. The microcontroller unit 116 may also report the detections external to the battery management system 96 via the bus interface circuit 112.

The microcontroller unit 116 implements one or more processors. Each processor may be embodied as a separate processor, an application specific integrated circuit (ASIC), a field programmable gate array (FPGA), or a dedicated electronic control unit. The microcontroller unit 116 may be any sort of electronic processor (implemented in hardware, software executing on hardware, or a combination of both). The microcontroller unit 116 may also include tangible, non-transitory memory, (e.g., read-only memory in the form of optical, magnetic, and/or flash memory). For example, the microcontroller unit 116 may include application-suitable amounts of random-access memory, read-only memory, flash memory and other types of electrically-erasable programmable read-only memory, as well as accompanying hardware in the form of a high-speed clock or timer, analog-to-digital and digital-to-analog circuitry, and input/output circuitry and devices, as well as appropriate signal conditioning and buffer circuitry.

Computer-readable and executable instructions embodying the present method may be stored in the memory and executed as set forth herein. The executable instructions may be a series of instructions employed to run applications on the one microcontroller unit 116 (either in the foreground or background). The microcontroller unit 116 may receive commands and information, in the form of one or more input signals from various controls or components in the system 90 and communicate instructions to the power board 104.

The high voltage measurement circuits 122a-122b implement voltage measuring and reporting devices. The high voltage measurement circuits 122a-122b are operational to measure the high voltage 136 of the high voltage current 138. The voltage measurements are presented to the high voltage sensing circuit 124.

The high voltage sensing circuit 124 is operational to report to the microcontroller unit 116 the high voltage current 138 and the high voltage 136 as measured by the high voltage measurement circuits 122a-122b. In various embodiments, the high voltage sensing circuit 124 includes an on/off detection capability that reports if the high voltage 136 is present (ON) or not (OFF).

Each transistor 126a-126b implements one or more power transistors. The transistors 126a-126b are operational to switch the high voltage 136 and the high voltage current 138 from an input node 140 of the power board 104 to an output node 142 of the power board 104. In various embodiments, the transistors 126a-126b may be metal- oxide-semiconductor field-effect transistors (MOSFETs). Other types of transistors may be implemented to meet the design criteria of a particular application.

The gate driver circuit 128 may be an IED13051AS single channel isolated IGBT/SiC-MOSFET driver available from Infineon Technologies AG, Munich, Germany. The gate driver circuit 128 is operational to switch on/off the transistors 126a-126b based on control signals received from the microcontroller unit 116.

The shunt 130 implements a low-resistance device in series with the high voltage current 138. The shunt 130 develops a voltage proportional to the current flowing within.

The shunt monitor circuit 132 implements a voltage sensing and reporting circuit. The shunt monitor circuit 132 is operational to measure the voltage generated across the shunt 130 and report the voltage to the microcontroller unit 116. In various embodiments, the shunt monitor circuit 132 includes an optional I2t (ampere squared seconds) calculation capability. The I2t calculation is based on the voltage across the shunt 130. The value of the I2t calculation may be reported to the microcontroller unit 116. The I2t calculation is a measurement of thermal energy associated with the high voltage current 138 flow in the power board 104.

The temperature sensing circuit 134 implements one or more temperature sensors. The temperature sensing circuit 134 is operational to measure and report the temperatures of the transistors 126a-126b to the microcontroller unit 116.

The pre-charge circuit 135 implements a series resistance and one or more switches (e.g., transistors). The pre-charge circuit 135 is operational to bypass the transistors 126a-126b while in an active state to provide a pre-charge signal that controls a pre-charge current that charges the capacitance 94. While in an inactive state, the pre-charge circuit 135 acts as a high impedance parallel to the transistors 126a-126b.

FIG. 2 illustrates a flow diagram of an example pre-charge detection and coordination method in accordance with one or more exemplary embodiments. The method (or process) 160 includes steps 161 to 172, as illustrated. The sequence of steps is shown as a representative example. Other step orders may be implemented to meet the criteria of a particular application.

The battery management system 96 may request in the step 161 that the capacitance 94 be pre-charged. In the step 162, the microcontroller unit 116 commands the pre-charge circuit 135 into the active state to send a pre-change current to the capacitance 94. The capacitance 94 is changed in the step 164 by the pre-charge current. The high-voltage sensing circuit 124 reports the measured voltage at the voltage measurement circuit 122b to the microcontroller unit 116. In the step 166, the microcontroller unit 116 determines if the pre-charge of the capacitance 94 is complete or not. If the pre-charge is complete per the step 166, the microcontroller unit 116 commands the gate driver 128 to switch on the transistors 126a-126b in the step 168. In the step 170, the gate driver 128 switches on the transistors 126a-126b. If the pre-charging is not complete per the step 166, the microcontroller unit 116 reports a fault to the battery management system 96 in the step 172.

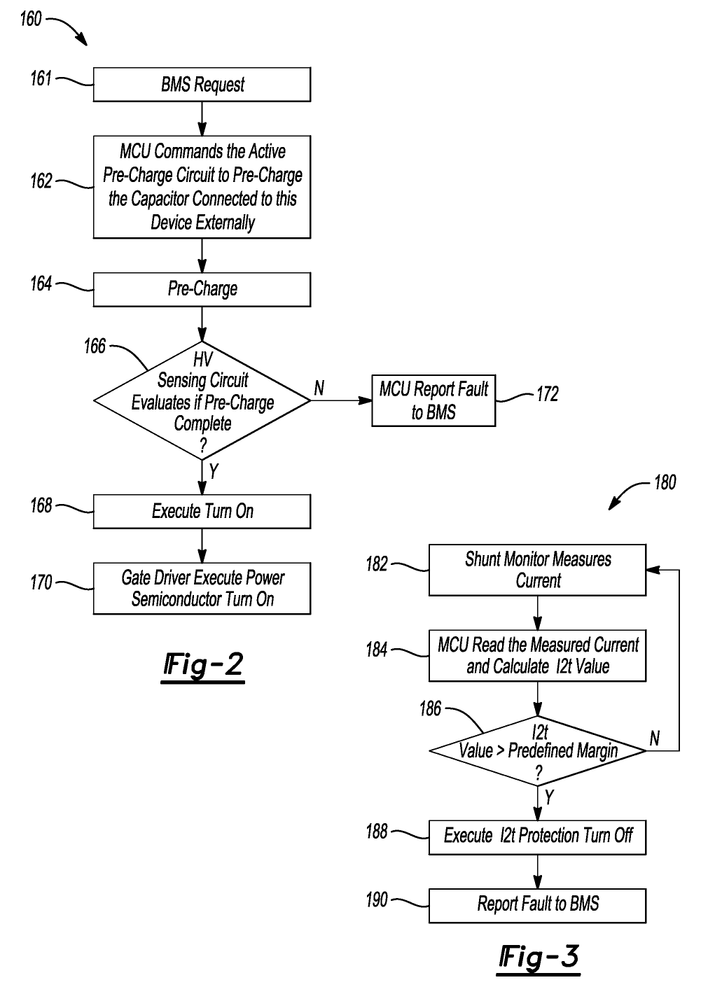

FIG. 3 illustrates a flow diagram of an example It2 calculation method in accordance with one or more exemplary embodiments. The method (or process) 180 includes steps 182 to 190, as illustrated. The sequence of steps is shown as a representative example. Other step orders may be implemented to meet the criteria of a particular application.

In the step 182, the shunt monitor circuit 132 measures the current flowing through the shunt 130 (e.g., I = V/R). The microcontroller unit 116 reads the measured current and calculates an I2t value in the step 184. If the I2t value is not greater than a predefined threshold per the step 186, the method 180 returns to the step 182 and measures the current again. If the It2 value is greater than the predefined threshold, the microcontroller unit 116 commands the transistors 126a-126b be opened in the step 188. The microcontroller unit 116 subsequently reports a fault to the battery management system 96 in the step 190.

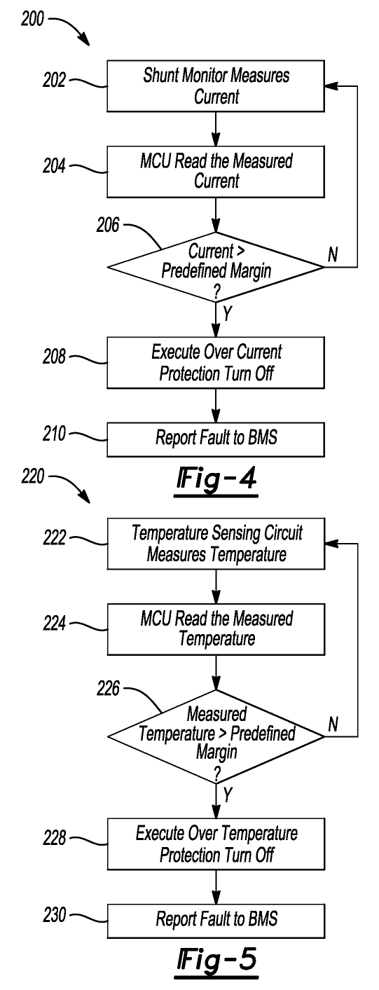

FIG. 4 illustrates a flow diagram of an example over current detection method in accordance with one or more exemplary embodiments. The method (or process) 200 includes steps 202 to 210, as illustrated. The sequence of steps is shown as a representative example. Other step orders may be implemented to meet the criteria of a particular application.

In the step 202, the shunt monitor circuit 132 measures the current flowing through the shunt 130. The microcontroller unit 116 reads the measured current in the step 204. If the measured current is not greater than a current threshold per the step 206, the method 200 returns to the step 202 and measures the current again. If the measured current is greater than the current threshold, the microcontroller unit 116 commands the transistors 126a-126b be opened in the step 208. The microcontroller unit 116 subsequently reports a fault to the battery management system 96 in the step 210.

FIG. 5 illustrates a flow diagram of an example over temperature detection method in accordance with one or more exemplary embodiments. The method (or process) 220 includes steps 222 to 230, as illustrated. The sequence of steps is shown as a representative example. Other step orders may be implemented to meet the criteria of a particular application.

In the step 222, the temperature sensing circuit 134 measures the temperature at one or more locations in the power board 104. The microcontroller unit 116 reads the measured temperature in the step 224. If the measure temperature is not greater than a temperature threshold per the step 226, the method 220 returns to the step 222 and measures the temperature again. If the measured temperature is greater than the temperature threshold, the microcontroller unit 116 command the transistors 124a-124b be opened in the step 228. The microcontroller unit 116 subsequently reports a fault to the battery management system 96 in the step 230.

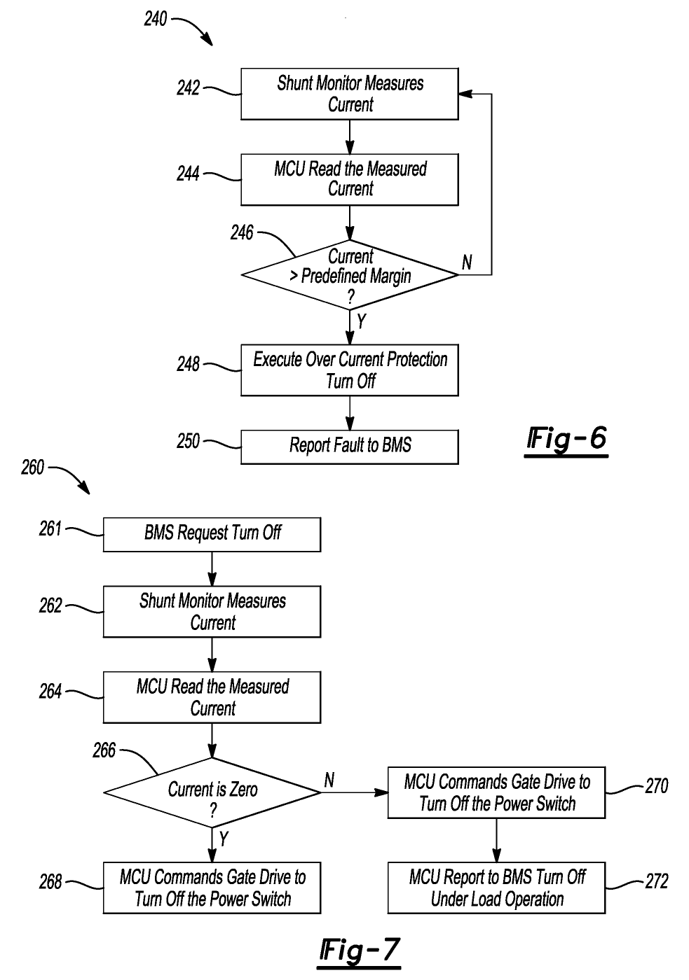

FIG. 6 illustrates a flow diagram of an example short circuit detection method in accordance with one or more exemplary embodiments. The method (or process) 240 includes steps 242 to 250, as illustrated. The sequence of steps is shown as a representative example. Other step orders may be implemented to meet the criteria of a particular application.

In the step 242, the shunt monitor circuit 132 measures the current flowing through the shunt 130. The microcontroller unit 116 reads the measured current in the step 244. If the measured current is not greater than a short-circuit threshold per the step 246, the method 240 returns to the step 242 and measures the current again. If the measured current is greater than the short-circuit threshold, the microcontroller unit 116 commands the transistors 126a-126b be opened in the step 248. The microcontroller unit 116 subsequently reports a fault to the battery management system 96 in the step 250.

FIG. 7 illustrates a flow diagram of an example circuit breaker control method in accordance with one or more exemplary embodiments. The method (or process) 260 includes steps 262 to 272, as illustrated. The sequence of steps is shown as a representative example. Other step orders may be implemented to meet the criteria of a particular application.

The battery management system 96 may request in the step 261 that the battery 92 be disconnected. In the step 262, the shunt monitor circuit 132 measures the current flowing through the shunt 130. The microcontroller unit 116 reads the measured current in the step 264. If the measured current is zero per the step 266, the microcontroller unit 116 commands the transistors 126a-126b be opened in the step 268. If the measured current is greater than zero in the step 266, the microcontroller unit 116 commands the gate driver 128 to switch off the transistors 126a-126b in the step 270. In the step 272, the microcontroller unit 116 reports the turn off under load states to the battery management system 96.

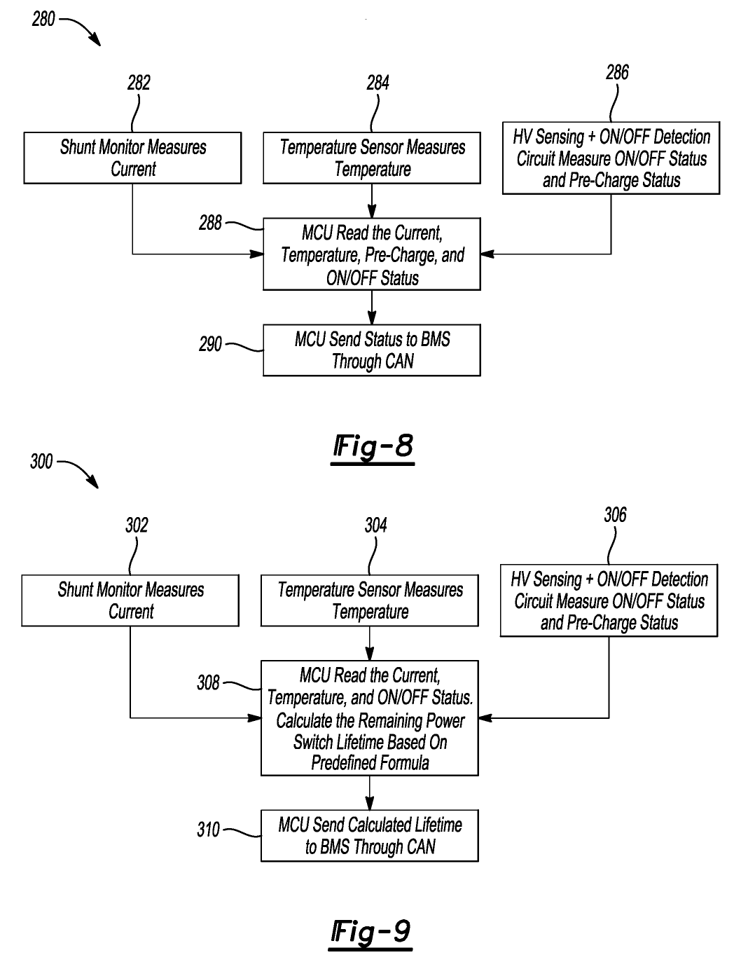

FIG. 8 illustrates a flow diagram of an example BMS interaction method in accordance with one or more exemplary embodiments. The method (or process) 280 includes steps 282 to 290, as illustrated. The sequence of steps is shown as a representative example. Other step orders may be implemented to meet the criteria of a particular application.

In the step 282, the shunt monitor circuit 132 measures the current flowing through the shunt 130. The temperature sensing circuit 134 measures the temperature in the step 284. In the step 286, the high voltage sensing circuit 124 measures the on/off status of the high voltage 136 and the pre-charge status of the pre-charge circuit 135. The microcontroller unit 116 reads the measured current, the measured temperature, the on/off status and the pre-charge status in the step 288. The microcontroller unit 116 subsequently reports measurement and status information to the battery management system 96 in the step 290.

FIG. 9 illustrates a flow diagram of an example solid-state switch degradation and end of life method in accordance with one or more exemplary embodiments. The method (or process) 300 includes steps 302 to 310, as illustrated. The sequence of steps is shown as a representative example. Other step orders may be implemented to meet the criteria of a particular application.

In the step 302, the shunt monitor circuit 132 measures the current flowing through the shunt 130. The temperature sensing circuit 134 measures the temperature in the step 304. In the step 306, the high voltage sensing circuit 124 measures the on/off status of the high voltage 136 and the pre-charge status of the pre-charge circuit 135. The microcontroller unit 116 reads the measured current, the measured temperature, the on/off status and the pre-charge status in the step 308. The microcontroller unit 116 calculates the estimated degradation and estimated remaining lifetime, and subsequently reports the information to the battery management system 96 in the step 310.

Embodiments of this disclosure include the micro controller unit, the current sensing circuitry, the voltage sensing, circuitry, and the temperature sensor in a solid-state switch. Software executing on the microcontroller unit may regulate these features, the following functions are achieved: pre-charge detection; and control; I2t calculations; over current detection; over temperature detection; and short circuit detection. Other advanced functions may be implemented in the software to meet the design criteria of a particular application.

An aspect of the invention includes a solid-state switch having a power board and a control board. The power board is operational to: alternatively switch on and switch off a high-voltage current with a plurality of transistors; measure the high-voltage current; and sense a high voltage of the high-voltage current. The control board operates from a low-voltage source and includes a microcontroller unit and a bus interface circuit. The control board is operational to: pass a plurality of control signals from the microcontroller unit to the power board for switching of the high-voltage current; and pass a plurality of sensed data from the power board to the microcontroller unit for the high voltage current and the high voltage. The microcontroller unit is operational to: calculate a plurality of detections that include a pre-charge detection, an ampere squared seconds detection, an over current detection, an over temperature detection, and a short circuit detection; and report the plurality of detections external to the control board via the bus interface circuit.

Another aspect of the disclosure includes a pre-charge circuit disposed on the power board and operational to route the high-voltage current around the plurality of transistors in response to a pre-charge signal to charge a capacitance.

In another aspect of the disclosure, the microcontroller unit is further operational to control the pre-charge circuit to charge the capacitance while the plurality of transistors are switched off.

In another aspect of the disclosure, the microcontroller unit is further operational to switch off the high voltage current in response to an ampere squared seconds value exceeding a predefined threshold.

In another aspect of the disclosure, the microcontroller unit is further operational to: read the high voltage current; and switch off the high-voltage current in response to the high voltage current exceeding a current threshold.

In another aspect of the disclosure, the microcontroller unit is further operational to: read a temperature on the power board; and switch off the high-voltage current in response to the temperature exceeding a temperature threshold.

In another aspect of the disclosure, the microcontroller unit is further operational to: read the high voltage current; and switch off the high-voltage current in response to the high voltage current exceeding a short-circuit threshold.

In another aspect of the disclosure, the microcontroller unit is further operational to: read the high voltage current, a temperature, the high voltage and a pre-charge status; and send a status report to a battery management system, the status report including the high voltage current, the temperature, the high voltage and the pre-charge status.

In another aspect of the disclosure, the microcontroller unit is further operational to: read the high voltage current, a temperature, the high voltage and a pre-charge status; calculate a remaining lifetime of the plurality of transistors based on the high voltage current, the temperature, the high voltage and the pre-charge status; and send the remaining lifetime to a battery management system.

An aspect of the disclosure includes a method for switching a high-voltage current. The method includes: alternatively switching on and switching off the high-voltage current with a plurality of transistors on a power board; measuring the high- voltage current; sensing a high voltage of the high-voltage current; passing a plurality of control signals from a microcontroller unit on a control board to the power board for switching of the high-voltage current; passing a plurality of sensed data from the power board to the microcontroller unit for the high voltage current and the high voltage; calculating a plurality of detections with the microcontroller unit, the plurality of detections include a pre-charge detection, an ampere squared seconds detection, an over current detection, an over temperature detection, and a short circuit detection; and reporting the plurality of detections external to the control board via a bus interface circuit of the control board.

Another aspect of the disclosure includes routing the high-voltage current around the plurality of transistors with a pre-charge circuit of the power board in response to a pre-charge signal to charge a capacitance.

Another aspect of the disclosure includes controlling the pre-charge circuit with the microcontroller unit to charge the capacitance while the plurality of transistors are switched off.

Another aspect of the disclosure includes switching off the high voltage current in response to an ampere squared seconds value exceeding a predefined threshold.

Another aspect of the disclosure includes reading the high voltage current at the microcontroller unit; and switching off the high-voltage current in response to the high voltage current exceeding a current threshold.

Another aspect of the disclosure includes reading a temperature on the power board at the microcontroller unit; and switching off the high-voltage current in response to the temperature exceeding a temperature threshold.

Another aspect of the disclosure includes reading the high voltage current at the microcontroller unit; and switching off the high-voltage current in response to the high voltage current exceeding a short-circuit threshold.

Another aspect of the disclosure includes reading the high voltage current, a temperature, the high voltage and a pre-charge status at the microcontroller unit; and sending a status report from the microcontroller unit to a battery management system, the status report including the high voltage current, the temperature, the high voltage and the pre-charge status.

Another aspect of the disclosure includes reading the high voltage current, a temperature, the high voltage and a pre-charge status at the microcontroller unit; calculating a remaining lifetime of the plurality of transistors with the microcontroller unit based on the high voltage current, the temperature, the high voltage and the pre-charge status; and sending the remaining lifetime from the microcontroller unit to a battery management system.

An aspect of the disclosure includes a system having a battery, a power board, a pre-charge circuit, a control board and a microcontroller unit. The battery has a capacitance. The power board is coupled to the capacitance and is operational to: alternatively switch on and switch off a high-voltage current with a plurality of transistors; measure the high-voltage current; and sense a high voltage of the high-voltage current. The pre-charge circuit is disposed on the power board and is operational to route the high-voltage current around the plurality of transistors to charge the capacitance. The control board operates from a low-voltage source and includes a microcontroller unit. The control board is operational to: pass a pre-charge signal to the pre-charge circuit for controlling a pre-charge of the capacitance; and pass a plurality of sensed data from the power board to the microcontroller unit for the high voltage current and the high voltage. The microcontroller unit is operational to: initiate the pre-charge; and stop the pre-charge in response to the high voltage reaching a threshold.

In another aspect of the disclosure, the microcontroller unit is further operational to generate a plurality of control signal for switching the high-voltage current after the pre-charge has completed. The control board is further operational to pass the plurality of control signals from the microcontroller unit to the power board for switching of the high-voltage current.

Those having ordinary skill in the art will recognize that terms such as “above,” “below,” “front,” “back,” “upward,” “downward,” “top,” “bottom,” etc., may be used descriptively herein without representing limitations on the scope of the disclosure. Furthermore, the present teachings may be described in terms of functional and/or logical block components and/or various processing steps. Such block components may be comprised of various hardware components, software components executing on hardware, and/or firmware components executing on hardware.

The foregoing detailed description and the drawings are supportive and descriptive of the disclosure, but the scope of the disclosure is defined solely by the claims. As will be appreciated by those of ordinary skill in the art, various alternative designs and embodiments may exist for practicing the disclosure defined in the appended claims.

1. A solid-state switch comprising:
a power board operational to:
alternatively switch on and switch off a high voltage current with a plurality of transistors;
measure the high-voltage current; and
sense a high voltage of the high-voltage current;
a control board that operates from a low-voltage source and includes a microcontroller unit and a bus interface circuit, wherein the control board is operational to:
pass a plurality of control signals from the microcontroller unit to the power board for switching of the high-voltage current; and
pass a plurality of sensed data from the power board to the microcontroller unit for the high voltage current and the high voltage;
the microcontroller unit is operational to:
calculate a plurality of detections that include a pre-charge detection, an ampere squared seconds detection, an over current detection, an over temperature detection, and a short circuit detection; and
report the plurality of detections external to the control board via the bus interface circuit.

2. The solid-state switch according to claim 1, further comprising:
a pre-charge circuit disposed on the power board and operational to route the high-voltage current around the plurality of transistors in response to a pre-charge signal to charge a capacitance.

3. The solid-state switch according to claim 2, wherein:
the microcontroller unit is further operational to control the pre-charge circuit to charge the capacitance while the plurality of transistors are switched off.

4. The solid-state switch according to claim 1, wherein the microcontroller unit is further operational to switch off the high voltage current in response to an ampere squared seconds value exceeding a predefined threshold.

5. The solid-state switch according to claim 1, wherein the microcontroller unit is further operational to:
read the high voltage current; and
switch off the high-voltage current in response to the high voltage current exceeding a current threshold.

6. The solid-state switch according to claim 1, wherein the microcontroller unit is further operational to:
read a temperature on the power board and
switch off the high-voltage current in response to the temperature exceeding a temperature threshold.

7. The solid-state switch according to claim 1, wherein the microcontroller unit is further operational to:
read the high voltage current; and
switch off the high-voltage current in response to the high voltage current exceeding a short-circuit threshold.

8. The solid-state switch according to claim 1, wherein the microcontroller unit is further operational to:
read the high voltage current, a temperature, the high voltage and a pre-charge status; and
send a status report to a battery management system, the status report including the high voltage current, the temperature, the high voltage and the pre-charge status.

9. The solid-state switch according to claim 1, wherein the microcontroller unit is further operational to:
read the high voltage current, a temperature, the high voltage and a pre-charge status;
calculate a remaining lifetime of the plurality of transistors based on the high voltage current, the temperature, the high voltage and the pre-charge status; and
send the remaining lifetime to a battery management system.

10. A method for switching a high-voltage current comprising:
alternatively switching on and switching off the high-voltage current with a plurality of transistors on a power board;
measuring the high-voltage current;
sensing a high voltage of the high-voltage current;
passing a plurality of control signals from a microcontroller unit on a control board to the power board for switching of the high-voltage current;
passing a plurality of sensed data from the power board to the microcontroller unit for the high voltage current and the high voltage;
calculating a plurality of detections with the microcontroller unit, the plurality of detections include a pre-charge detection, an ampere squared seconds detection, an over current detection, an over temperature detection, and a short circuit detection; and
reporting the plurality of detections external to the control board via a bus interface circuit of the control board.

11. The method according to claim 10, further comprising:
routing the high-voltage current around the plurality of transistors with a pre-charge circuit of the power board in response to a pre-charge signal to charge a capacitance.

12. The method according to claim 11, further comprising:
controlling the pre-charge circuit with the microcontroller unit to charge the capacitance while the plurality of transistors are switched off.

13. The method according to claim 10, further comprising:
switching off the high voltage current in response to an ampere squared seconds value exceeding a predefined threshold.

14. The method according to claim 10, further comprising:
reading the high voltage current at the microcontroller unit; and
switching off the high-voltage current in response to the high voltage current exceeding a current threshold.

15. The method according to claim 10, further comprising:
reading a temperature on the power board at the microcontroller unit; and
switching off the high-voltage current in response to the temperature exceeding a temperature threshold.

16. The method according to claim 10, further comprising:
reading the high voltage current at the microcontroller unit; and
switching off the high-voltage current in response to the high voltage current exceeding a short-circuit threshold.

17. The method according to claim 10, further comprising:
reading the high voltage current, a temperature, the high voltage and a pre-charge status at the microcontroller unit; and
sending a status report from the microcontroller unit to a battery management system, the status report including the high voltage current, the temperature, the high voltage and the pre-charge status.

18. The method according to claim 10, further comprising:
reading the high voltage current, a temperature, the high voltage and a pre-charge status at the microcontroller unit;
calculating a remaining lifetime of the plurality of transistors with the microcontroller unit based on the high voltage current, the temperature, the high voltage and the pre-charge status; and
sending the remaining lifetime from the microcontroller unit to a battery management system.

19. A system comprising:
a battery having a capacitance;
a power board coupled to the capacitance and operational to:
alternatively switch on and switch off a high-voltage current with a plurality of transistors;
measure the high-voltage current; and
sense a high voltage of the high-voltage current;
a pre-charge circuit disposed on the power board and operational to route the high-voltage current around the plurality of transistors to charge the capacitance;
a control board that operates from a low-voltage source and includes a microcontroller unit, wherein the control board is operational to:
pass a pre-charge signal to the pre-charge circuit for controlling a pre-charge of the capacitance; and
pass a plurality of sensed data from the power board to the microcontroller unit for the high voltage current and the high voltage;
the microcontroller unit is operational to:
initiate the pre-charge; and
stop the pre-charge in response to the high voltage reaching a threshold.

20. The system according to claim 19, wherein:
the microcontroller unit is further operational to generate a plurality of control signal for switching the high-voltage current after the pre-charge has completed; and
the control board is further operational to pass the plurality of control signals from the microcontroller unit to the power board for switching of the high-voltage current.
